(19) United States
(12) Patent Application Publication
(10) Pub. No.: US 2005/0006659 A1
(43) Pub. Date: Jan. 13, 2005

(54) Light emitting diode utilizing a discrete wavelength-converting layer for color conversion

(76) Inventors: Kee Yean Ng, (US); Wen Ua Ou, Tanjung Tokong (MY)

Correspondence Address: AGILENT TECHNOLOGIES, INC.;Legal Department, DLA29, Intellectual Property Administration, P.O. Box 7599, Loveland, CO, 80537-0599, US

(21) Appl. No.: 10/616,759

(22) Filed: Jul. 9, 2003

(51) Int. Cl. H01L 33/00

(52) U.S. Cl. 257/99

(57) ABSTRACT

A method for fabrication of a light source and the light source fabricated by that method are disclosed. The light source is fabricated by mounting a chip having a primary light source on a substrate, the primary light source emitting light of a first wavelength. The chip is connected to power terminals on the substrate for powering the primary light source. A preformed transparent cap of constant thickness is mounted over the chip. The cap includes a wavelength converting material for converting a portion of the light of the first wavelength to a second wavelength. The primary light source is preferably an LED or laser diode. In one embodiment, the cap includes a phosphor that is suspended in a clear compound. In another embodiment, the cap includes a planar sheet of a single crystal phosphor.

### BACKGROUND OF THE INVENTION

The present invention can be more easily understood with reference to LEDs that appear to emit white light. LEDs have higher efficiency and other characteristics that make them attractive candidates for replacing incandescent and fluorescent lights. Unfortunately, LEDs produce light in a relatively narrow spectral band. Hence, to provide a LED-based white light source, either multiple sources must be combined in a manner that allows the light to be uniformly mixed or some form of light conversion must be utilized to convert part of the LED light to light of a different color. One method for constructing a light source that is perceived by a human observer as white utilizes a phosphor to convert a portion of the light from a blue-emitting LED to yellow light having a broad band of wavelengths. The blue light that is not converted by the phosphor is mixed with the yellow light. If the ratio of blue to yellow light is properly adjusted, the resultant light appears white.

These prior art white light sources typically utilize an arrangement in which a semiconductor chip having a blue-emitting LED thereon is covered by a layer of epoxy having particles of a conversion phosphor therein. These particles convert the blue light to yellow as described above. This arrangement has a number of problems. First, the deposition of a layer of uniform thickness is difficult. Since color uniformity requires a uniform thickness, color uniformity is difficult to guarantee. In areas where the phosphor is thicker, the light appears more yellowish white, while in sections having a thinner phosphor layer the light appears bluish white.

Second, these phosphor particles are polycrystalline. Polycrystalline phosphor tends to be opaque. As a result, the phosphor particles absorb light, which lowers the light output. In addition, particles scatter the blue light, leading to lower light extraction efficiency. Third, the particles tend to agglomerate, and hence, providing a uniform layer with particles of a known size is difficult.

### SUMMARY OF THE INVENTION

The present invention includes a method for fabrication of a light source and the light sources fabricated by that method. The light source is fabricated by mounting a chip having a primary light source on a substrate, the primary light source emitting light of a first wavelength. The chip is connected to power terminals on the substrate for powering the primary light source. A preformed transparent cap of constant thickness is mounted over the chip. The cap includes a wavelength converting material for converting a portion of the light of the first wavelength to a second wavelength. The primary light source is preferably an LED or laser diode. In one embodiment, the cap includes a phosphor that is suspended in a clear compound. In another embodiment, the cap includes a planar sheet of a single crystal phosphor. Embodiments in which the cap includes an inverted cavity with the chip on the concave side of the cavity can also be constructed.

### BRIEF DESCRIPTION OF THE DRAWINGS

FIG. 1 is a cross-sectional view of a prior art white-light emitting LED 10.

FIG. 2 is a cross-sectional view of a light source 100 according to one embodiment of the present invention.

FIG. 3 is a cross-sectional view of a light source 200 according to another embodiment of the present invention.

FIG. 4 is a cross-sectional view of a light source 300 according to another embodiment of the present invention.

### DETAILED DESCRIPTION OF THE PREFERRED EMBODIMENTS OF THE INVENTION

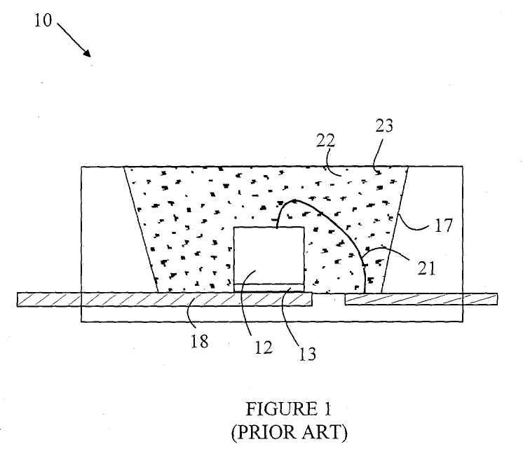

The manner in which the present invention provides its advantages can be more easily understood with reference to FIG. 1, which is cross-sectional view of a prior art white-light emitting LED 10. Light source 10 includes a reflecting cup 17 constructed in a well in a printed circuit board base. Semiconductor chip 12 having a primary light source is mounted on a conductor 18 on the bottom of cup 17 with the aid of an adhesive layer 13. The chip is electrically connected to an off-chip power source via contact 21 and conductor 18 to the bottom of the chip. Cup 17 is filled with a casting epoxy 22 in which the phosphor particles 23 are suspended.

If the primary light source on semiconductor chip 12 is a blue-emitting LED or laser diode, then the phosphor particles are chosen to convert blue light to yellow light. For example, an LED that emits blue radiation, typically at about 480 nm, is used to excite a YAG:Ce phosphor which then re-emits a broad-band yellowish radiation. Not all of the blue radiation is absorbed by the phosphor. The unabsorbed portion of the blue radiation and the yellow radiation, in combination, are perceived as white to a human observer because blue and yellow are complementary colors.

To provide a white source, the layer of phosphor material must be uniform. Variations in thickness of more than 20% result in easily discernable color variations. Any lack of uniformity leads to a light source whose color varies over the area of the light source. Areas of the light source in which the layer is too thin will have a bluish white appearance, and areas in which the layer is too thick will have a yellowish appearance. As noted above, creating such a uniform layer with a cast epoxy system is difficult. The phosphor particles tend to settle when the mixed material is allowed to stand and during the curing process. In addition, the epoxy layer is subject to non-uniform shrinkage during the curing process. Thirdly, the geometry of the device inherently causes light that is emitted from the vertical sides of the LED to traverse through a thicker phosphor layer than the light that is emitted from the top horizontal surface of the LED. Hence, while prior art devices attempt to provide a phosphor layer of constant thickness, in practice, the layer is not sufficiently constant in thickness to provide a light source having a constant color across the source.

In addition to the problems associated with curing the epoxy in the reflecting cup, the particulate nature of the phosphor particles also introduces problems. Polycrystalline phosphor particles both absorb and scatter the light from the chip. In addition, the particles tend to agglomerate. Hence, these prior art light sources have less than ideal light extraction efficiency.

The present invention overcomes these problems by utilizing a phosphor cap that is formed separately via a process that assures a uniform thickness of the phosphor material. The cap is then positioned over the LED chip thereby assuring that a uniform layer of phosphor is positioned to convert a predetermined fraction of the light generated by the LED.

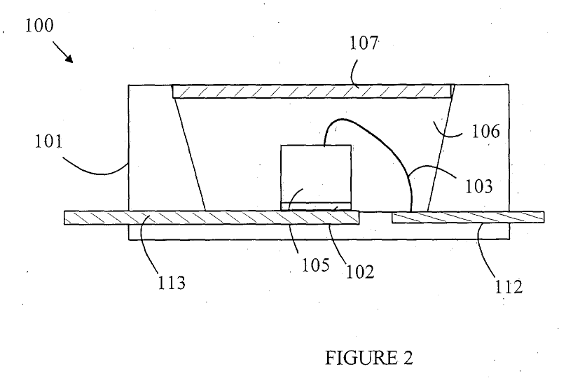

The manner in which the present invention provides its advantages can be more easily understood with reference to FIG. 2, which is a cross-sectional view of a light source 100 according to one embodiment of the present invention. Light source 100 utilizes a single crystal semiconductor material suitably doped to have fluorescent properties. Such a material will be referred to as a single crystal phosphor in the following discussion. This single crystal phosphor is used to provide the color conversion. This wavelength-conversion layer 107 is placed along the path of the light emitted by the LED. A portion of the radiation from LED 105 is absorbed by phosphor layer 107 which re-emits radiation of a different wavelength. The re-emitted radiation and any unabsorbed radiation from the LED form a composite light signal that appears white to an observer.

The single crystal phosphor can be grown using bulk crystal growth methods such as the Czochralsky method or epitaxial methods such as liquid or vapour phase epitaxy. For example, U.S. Pat. No. 4,873,062, which is hereby incorporated by reference, describes an apparatus and method for growing single crystals by this method. Since this method is well known in the semiconductor materials industry, it will not be discussed in detail here. For the purpose of this discussion, it is sufficient to note that a single-crystal phosphor is grown by lowering a single seed into a crucible having molten phosphor material. The bulk crystal is pulled from the molten material as the crystal grows. The bulk crystal is then sliced into thin layers and cut or broken into smaller pieces suitable for the use of this invention. In one preferred embodiment, the thickness of the layer is between 0.05 to 5 mm, more preferably 0.25 mm.

In the embodiment shown in FIG. 2, blue LED 105 is first mounted on a cavity shaped substrate 101 using an adhesive layer 102. An electrical connection 103 is made from one of the terminals of LED 105 to a terminal 112 . The second power connection is made from the bottom of the LED via terminal 113. The cavity contains a first layer of an optically clear encapsulant 106 and a second layer 107 of single-crystal phosphor at the top. While this embodiment utilizes a single-crystal layer that is at the top of the cavity, it should be noted that layer 107 can be placed at any location within the cavity.

As the single-crystal phosphor layer is transparent, it does not impede the transmission of light and scattering is minimized. Since the light conversion phosphor layer has a uniform thickness, the color conversion effect is the same across the surface, providing a more uniform composite light than prior art devices.

The choice of crystal material depends on the specific application. For white LEDs, the LED emits light in a first band and the light conversion layer converts a portion of that light to light in a complementary band. For example, white LEDs in which the LED that emits blue light, can utilize a suitable single-crystal phosphor comprising Yttrium Aluminum Garnet activated by cerium, YAG:Ce which converts blue light to yellow light. Similarly, LEDs which emits cyan (blue-green) can be matched with a single crystal phosphor that emits red to provide a light source that appears to be white.

It should be noted that multiple phosphor layers could also be utilized. For example, if a UV-emitting LED is utilized, at least two phosphors are needed to provide a source that is perceived as being white by an observer. In this case, phosphor layer 107 may include two separate phosphor layers, one for each phosphor. Each phosphor layer converts a portion of the UV light. Preferably, all of the UV light is converted by the combination of phosphors.

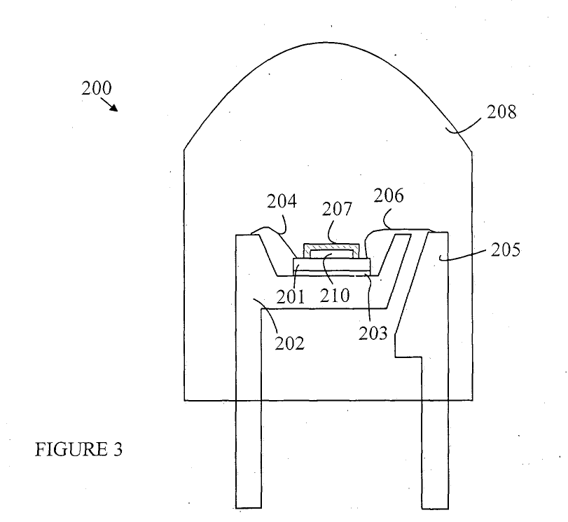

While the above-described embodiments of the present invention have utilized a phosphor layer constructed from a slice of a single crystal, other forms of phosphor layer can also be utilized. Refer now to FIG. 3, which is a cross-sectional view of a light source 200 according to another embodiment of the present invention. In this embodiment, a blue flip-chip LED 210, placed on a submount 201, is mounted on a cavity shaped substrate 202 using an adhesive 203. An electrical connection 204 is made from one of the terminals of the LED to substrate 202 while another electrical connection 206 is made from the other terminal of the LED to a second substrate 205. A uniform thickness phosphor cap 207 covers over the LED and a clear layer of encapsulant 208 then covers the whole assembly.

The phosphor cap is fabricated using a separate process such as transfer molding, injection molding or casting. In a preferred embodiment, the phosphor is mixed with a transparent medium such as epoxy, silicone, polycarbonate, acrylic, polyurethane, polypropylene and similar plastics or polymer and then formed into the desired shape by molding, casting, or other suitable process. Inorganic glass of low melting point can also be used as the transparent medium. The phosphor is preferably a material that does not present the scattering problems described above with respect to the inorganic phosphors that are utilized in white LEDs. For example, an organic luminescent material such as a fluorescent dye can be utilized.

However, it should be noted that inorganic phosphor powders can also be advantageously utilized. Preferably, such powders scatter less than 50 percent of the light. The uniform layer thickness provided by the present invention overcomes the color variations discussed above, and hence, the present invention still provides a significant advantage over the prior art methods discussed above. In addition, the transparent medium utilized to form the phosphor cap can be chosen from a much wider range of materials, since the fabrication process does not need to be restricted to processes that will not damage the LED. As a result, a material having an index of refraction that more nearly matches that of the phosphor material can be utilized, thereby reducing the light scattering. For example, a low melting point glass can be utilized as the casting material to reduce the difference in index of refraction between the phosphor particles and the casting material.

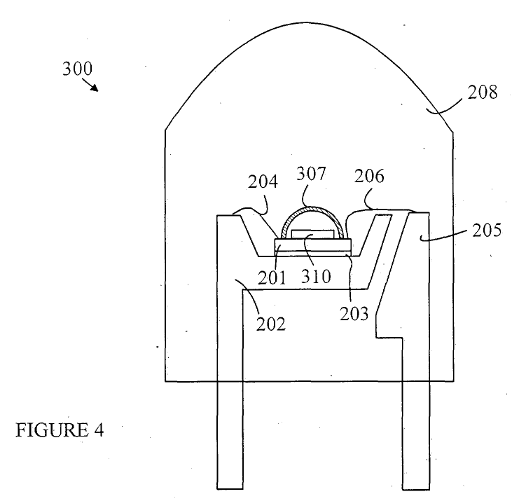

The above-described embodiments of the present invention utilized a phosphor cap having a particular shape. However, a wide variety of shapes can be utilized without departing from the teachings of the present invention. Refer now to FIG. 4, which is a cross-sectional view of a light source 300 according to another embodiment of the present invention. To simplify the following discussion, those elements of light source 300 that perform the same functions as corresponding elements of light source 200 shown in FIG. 3 have been given the same numeric designations and will not be discussed further here. Light source 300 utilizes a dome-shaped phosphor cap 307 to convert a portion of the light from a primary light source on chip 310 to a longer wavelength. While the preferred primary light source on chip 310 is an LED, other light sources such as a semiconductor laser can be utilized.

The dome-shaped phosphor cap shown in FIG. 4 is well matched to primary light sources that emit light over an area having dimensions that are small compared to the radius of curvature of cap 307. In this case, the thickness of phosphor containing medium through which the light passes is substantially independent of the angle of emission of the light from the primary light source.

The above-described embodiments of the present invention utilized a phosphor cap having a single phosphor therein. However, light sources based on multiple phosphors can also be constructed without departing from the teachings of the present invention. For example, if a UV light source is used as the primary light source, at least two phosphors are needed to provide a white appearing light source. The individual phosphors can be mixed together in the casting material before the cap is formed or multiple concentric caps can be utilized with a different phosphor in each cap.

The above-described embodiments of the present invention have been directed to light sources that emit light that is perceived to be “white” by the observer. However, the present invention can be utilized to construct other light sources that operate by converting a portion of the light emitted by a primary light source utilizing a phosphor.

Various modifications to the present invention will become apparent to those skilled in the art from the foregoing description and accompanying drawings. Accordingly, the present invention is to be limited solely by the scope of the following claims.

1. A method for fabricating a light source comprising:
mounting a chip having a primary light source on a substrate, said primary light source emitting light of a first wavelength;
connecting power terminals on said chip to corresponding power terminals on said substrate for powering said primary light source; and
mounting a preformed transparent cap over said chip, said cap comprising a wavelength-converting material for converting a portion of said light of said first wavelength to a second wavelength.

2. The method of claim 1 wherein said primary light source comprises an LED.

3. The method of claim 1 wherein said primary light source comprises a laser diode.

4. The method of claim 1 wherein said transparent cap comprises a phosphor material suspended in a clear compound.

5. The method of claim 1 wherein said transparent cap comprises a planar sheet of a single crystal phosphor.

6. The method of claim 1 wherein said transparent cap comprises an inverted cavity, said chip being on a concave side of said cavity.

7. The method of claim 1 wherein said transparent cap comprises a spherical surface of constant thickness.

8. The method of claim 1 wherein said transparent cap comprises a planar sheet having a constant thickness.

9. A light source comprising:
a chip having a primary light source mounted on a substrate, said primary light source emitting light of a first wavelength, said chip having chip power terminals connected to corresponding terminals on said substrate for powering said primary light source; and
a transparent cap over said chip, said cap comprising a wavelength-converting material for converting a portion of said light of said first wavelength to a second wavelength and for transmitting the portion of said light that is not converted, said transparent cap comprising a layer of wavelength-converting material of a constant thickness.

10. The light source of claim 9 wherein said transmitted portion of said light is transmitted without scattering more than 50 percent of said transmitted light.

11. The light source of claim 9 wherein said primary light source comprises an LED.

12. The light source of claim 9 wherein said primary light source comprises a laser diode.

13. The light source of claim 9 wherein said transparent cap comprises a phosphor suspended in a transparent material.

14. The light source of claim 9 wherein said transparent cap comprises a planar sheet of a single crystal phosphor.

15. The light source of claim 9 wherein said transparent cap comprises an inverted cavity, said chip being on a concave side of said cavity.

16. The light source of claim 9 wherein said transparent cap comprises a spherical surface of constant thickness.
